(19) United States
(12) Patent Application Publication
(10) Pub. No.: US 2005/0264996 A1
(43) Pub. Date: Dec. 1, 2005

(54) Pump, cooling unit and electronic apparatus including cooling unit

(76) Inventors: Kentaro Tomioka, Sayama-shi (JP); Katsumi Hisano, Matsudo-shi (JP); Tomonao Takamatsu, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/140,816

(22) Filed: May 31, 2005

(30) Foreign Application Priority Data
Jun. 1, 2004 (JP) 2004-163406

(51) Int. Cl. F04B 17/00; H05K 7/20

(52) U.S. Cl. 361/695; 417/353

(57) ABSTRACT

A pump has a pump casing and an impeller. The pump casing has a pump chamber, an inlet path through which a liquid is guided to the pump chamber and an outlet path through which the liquid is discharged from the pump chamber. The impeller is housed in the pump chamber. With the rotation of the impeller, the liquid is sucked through the inlet path into the pump chamber and pushed out of the pump chamber into the outlet path. The outlet path has a first opening end which is opened in the pump chamber, and a second opening end located downstream of the first opening end. The first opening end has an opening area larger than that of the second opening end.

### CROSS-REFERENCE TO RELATED APPLICATIONS

This application is based upon and claims the benefit of priority from prior Japanese Patent Application No. 2004-163406, filed Jun. 1, 2004, the entire contents of which are incorporated herein by reference.

### BACKGROUND OF THE INVENTION

1. Field of the Invention

The present invention relates to a pump having an inlet path and an outlet path that are opened to a pump chamber, and a cooling unit of a liquid cooling type which cools a heat generating component, for example, a CPU. The present invention also relates to an electronic apparatus, such as a portable computer equipped with the cooling unit.

2. Description of the Related Art

A CPU used in, for example, a portable computer tends to generate increased heat during operation, as the processing speed is increased or the functions thereof are expanded. If the temperature of the CPU rises too high, the CPU cannot operate efficiently or may be brought down.

To increase the cooling capacity of the CPU, in recent years, a so-called liquid cooling-type cooling system has been put into practical use. The conventional cooling system of this type has a heat exchange-type pump, a radiator and a circulation path. The heat exchange-type pump is thermally connected to the CPU. The radiator, for radiating the heat from the CPU, is provided in a position apart from the CPU. The circulation path is connected between the heat exchange-type pump and the radiator, and filled with a liquid coolant.

The liquid coolant absorbs the heat generated from the CPU through the heat exchange by the heat exchange-type pump. The liquid coolant thus heated is sent from the heat exchange-type pump to the radiator through the circulation path. The liquid coolant radiates the heat in the process of passing through the radiator. The liquid coolant cooled by the radiator returns to the heat exchange-type pump through the circulation path, and absorbs the heat from the CPU again. By this circulation of the liquid coolant, the heat of the CPU is successively transmitted to the radiator, and radiated to the outside of the portable computer.

The heat exchange-type pump used in the cooling system has a flat pump casing, an impeller housed in the pump casing, and a motor which rotates the impeller. The pump casing has a cylindrical wall, which surrounds the impeller. The cylindrical wall forms a pump chamber inside the pump casing. The impeller is housed in the pump chamber.

The pump casing has an inlet path, through which the liquid coolant is guided to the pump chamber, and an outlet path, through which the liquid coolant is discharged from the pump chamber. The inlet path and the outlet path are arranged side by side and extend outward in a radial direction of the impeller.

In the conventional heat exchange-type pump, each of the inlet path and the outlet path has a first open end, which opens to the pump chamber, and a second open end, which is opposite to the first open end. The first open end is located at the cylindrical wall of the pump casing and faces the periphery of the impeller.

When the impeller rotates, the liquid coolant is sucked in the pump chamber through the first open end of the inlet path. The sucked liquid coolant flows in the pump chamber toward the outlet path, and compressed in the process of the flow. Most part of the liquid coolant compressed in the pump chamber is discharged toward the radiator through the outlet path. For example, Jpn. Pat. Appln. KOKAI Publication No. 2003-172286 and Japanese Patent No. 3452059 disclose a cooling system having such a pump.

In the pumps disclosed in these Japanese publications, the diameter of the outlet path is substantially the same throughout its length. In other words, there is no technical means devised to smoothly guide the compressed liquid coolant from the pump chamber to the outlet path. Therefore, in the connecting portion between the pump chamber and the outlet path, the path of the flow of the liquid coolant is abruptly reduced and the pressure near the first open end of the outlet path in the pump chamber is locally increased.

As a result, the liquid coolant in the pump chamber stagnates in the portion near the first open end of the outlet path. Therefore, the liquid coolant compressed in the pump chamber cannot be efficiently discharged through the outlet path. Accordingly, the liquid coolant cannot be efficiently circulated along the circulation path. This disturbs transmission of the heat from the CPU to the radiator.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer according to a first embodiment of the present invention;

FIG. 2 is a partially sectioned side view of the portable computer of the first embodiment, showing an internal structure of a main unit which houses a cooling unit;

FIG. 3 is a bottom view of the portable computer of the first embodiment;

FIG. 4 is a partially sectioned plan view of a cooling unit housed in a first housing of the first embodiment;

FIG. 5 is a sectional view showing the positional relationship between a CPU and a heat exchange-type pump of the first embodiment;

FIG. 6 is an exploded perspective view of the heat exchange-type pump of the first embodiment;

FIG. 7 is an exploded perspective view of the heat exchange-type pump of the first embodiment;

FIG. 8 is a plan view of the heat exchange-type pump of the first embodiment;

FIG. 9 is a plan view showing the positional relationship among a casing body, an impeller and a connection block of the first embodiment;

FIG. 10 is a sectional view of a pump casing of the first embodiment, showing the shapes of an inlet path and an outlet path;

FIG. 11 is a perspective view showing a state in which the casing body is separated from the connection block in the first embodiment;

FIG. 12 is a side view of the connection block of the first embodiment;

FIG. 13 is a sectional view of the connection block of the first embodiment;

FIG. 14 is a sectional view of a radiator of the first embodiment;

FIG. 15 is a perspective view of a radiator block showing the positional relationship between heat radiating fins and a coolant path of the first embodiment;

FIG. 16 is a sectional view showing the positional relationship between a CPU and a heat exchange-type pump according to a second embodiment of the present invention; and

FIG. 17 is an exploded perspective view of the heat exchange-type pump of the second embodiment.

### DETAILED DESCRIPTION OF THE INVENTION

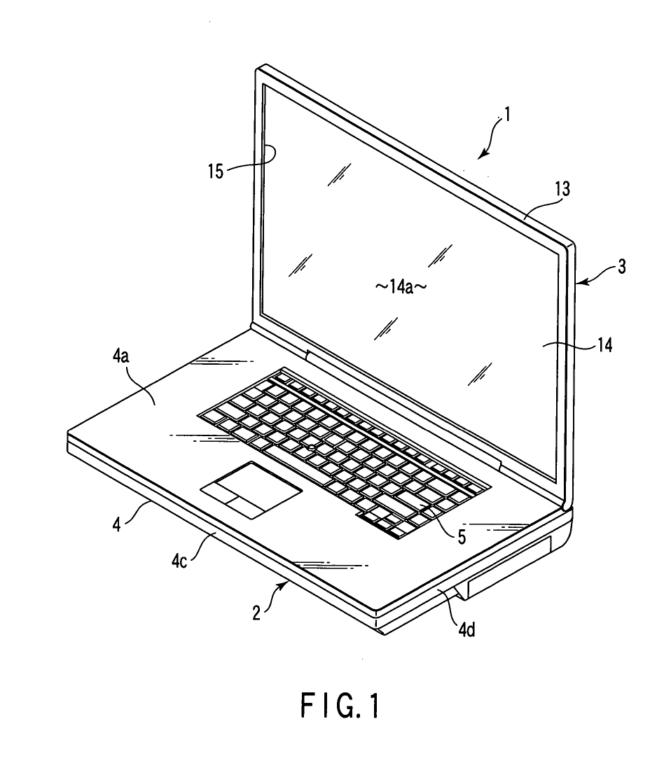

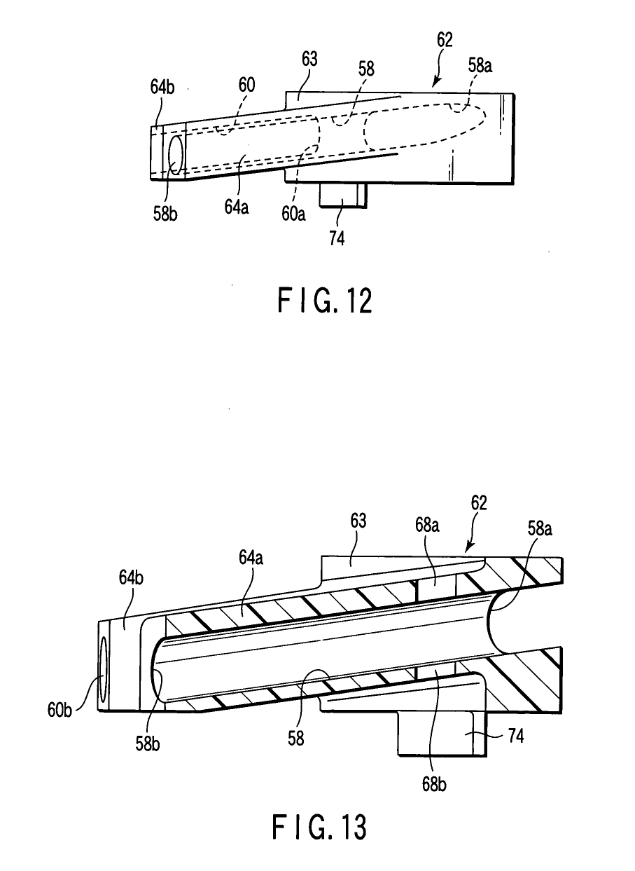

A first embodiment of the present invention will be described with reference to FIGS. 1 to 15.

FIGS. 1 to 3 disclose a portable computer 1 as an example of electronic apparatus. The portable computer 1 comprises a main unit 2 and a display unit 3. The main unit 2 has a flat box-shaped first housing 4. The first housing 4 has an upper wall 4a, a bottom wall 4b, a front wall 4c, left and right side walls 4d and a rear wall 4e. The upper wall 4a supports a keyboard 5.

The bottom wall 4b has a projected portion 6 and a recessed portion 7. The projected portion 6 is located in a back half portion of the bottom wall 4b and project downward relative to the front half portion of the bottom wall 4b. The recessed portion 7 is located immediately in front of the projected portion 6. The recessed portion 7 is recessed into the inner portion of the first housing 4.

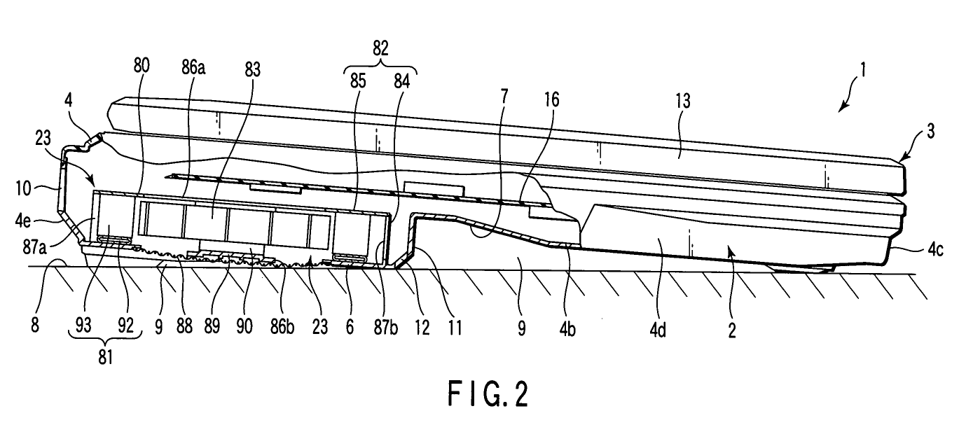

FIG. 2 shows a state in which the main unit 2 of the portable computer 1 is placed on, for example a top plate 8 of a desk. The first housing 4 of the main unit 2 is inclined forward on the top plate 8. There are gaps 9 between the bottom of the projected portion 6 and the top plate 8 and between the bottom wall 4b and the top plate 8.

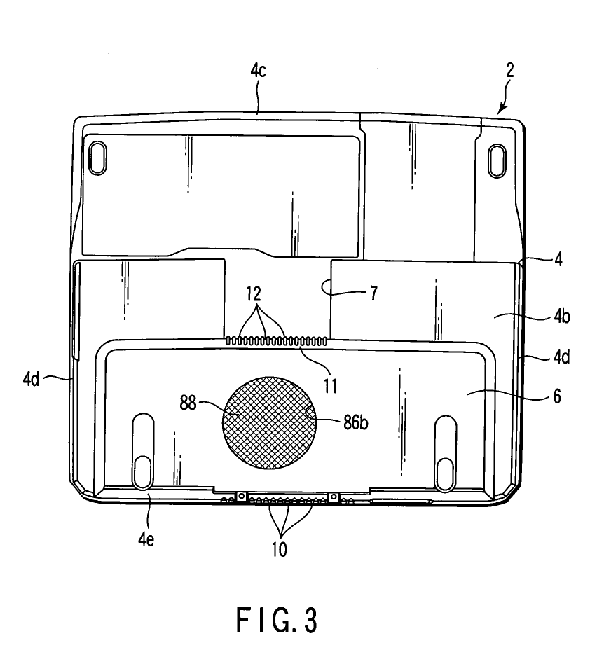

As shown in FIGS. 2 and 3, a plurality of first exhaust ports 10 are formed in the rear wall 4e of the first housing 4. The first exhaust ports 10 are arranged in a line in the width direction of the first housing 4. The projected portion 6 has a dividing wall 11, which divides the projected portion 6 from the recessed portion 7. A plurality of second exhaust ports 12 are formed in the dividing wall 11. The second exhaust ports 12 are arranged in a line in the width direction of the first housing 4 and opened to the recessed portion 7.

The display unit 3 has a second housing 13 and a liquid crystal display panel 14. The liquid crystal display panel 14 is housed in the second housing 13. The liquid crystal display panel 14 has a screen 14a. The screen 14a is exposed to the outside of the second housing 13 through an opening 15 formed in the front surface of the second housing 13.

The second housing 13 of the display unit 3 is supported by the rear end portion of the first housing 4 via a hinge (not shown). The display unit 3 is rotatable between a closed position and an open position. In the closed position, the display unit 3 lies on the main unit 2 to cover the keyboard 5 from above. In the open position, the display unit 3 stands so as to expose the keyboard 5 and the screen 14a.

As shown in FIGS. 2, 4 and 5, the first housing 4 houses a printed circuit board 16. A CPU 17 is mounted on an upper surface of a back portion of the printed circuit board 16. The CPU 17 is an example of heat generating components. The CPU 17 has a base structure 18 and an IC chip 19, which is mounted on a central portion of the upper surface of the base structure 18. The IC chip 19 generates a great amount of heat, as it is operated at a high processing speed and has many functions. Therefore, the IC chip 19 needs cooling to maintain stable operations.

The first housing 4 houses a cooling unit 21 of a liquid cooling type. The cooling unit 21 cools the CPU 17 by means of a liquid coolant, such as water or an antifreezing solution. The cooling unit 21 includes a heat exchange-type pump 22, a radiator 23 and a circulation path 24.

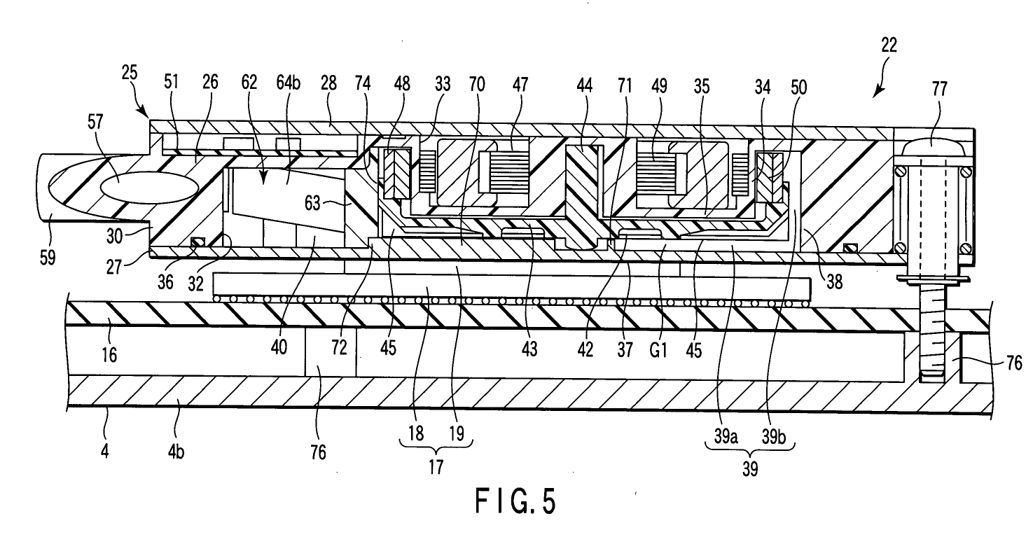

The heat exchange-type pump 22 also serves as a heat receiving portion. As shown in FIGS. 5 to 10, the heat exchange-type pump 22 has a pump casing 25. The pump casing 25 comprises a casing body 26, a heat receiving cover 27 and a back plate 28. The casing body 26 is a flat rectangular box, which is a size larger than the CPU 17 and made of, for example, heat resistant synthetic resin material. The casing body 26 has first to fourth corner portions 29a to 29d. The first corner portion 29a has an oblique side portion 30 connecting the two adjacent side surfaces of the casing body 26.

Further, the casing body 26 has a first recess portion 32 and a second recess portion 33. The first recess portion 32 is opened in the lower surface of the casing body 26. The second recess portion 33 is opened in the upper surface of the casing body 26. The second recess portion 33 has a cylindrical wall 34 and a circular end wall 35 located at the lower end of the cylindrical wall 34. The cylindrical wall 34 and the end wall 35 are located inside the first recess 32.

The heat receiving cover 27 is made of metal having a high thermal conductivity, for example, copper or aluminum. The heat receiving cover 27 is fixed to the lower surface of the casing body 26. The heat receiving cover 27 closes the open end of the first recess portion 32 and faces the end wall 35 of the second recess portion 33. The lower surface of the heat receiving cover 27 is a flat heat receiving surface 37. An O-ring 36 is interposed between the heat receiving cover 27 and the lower surface of the casing body 26.

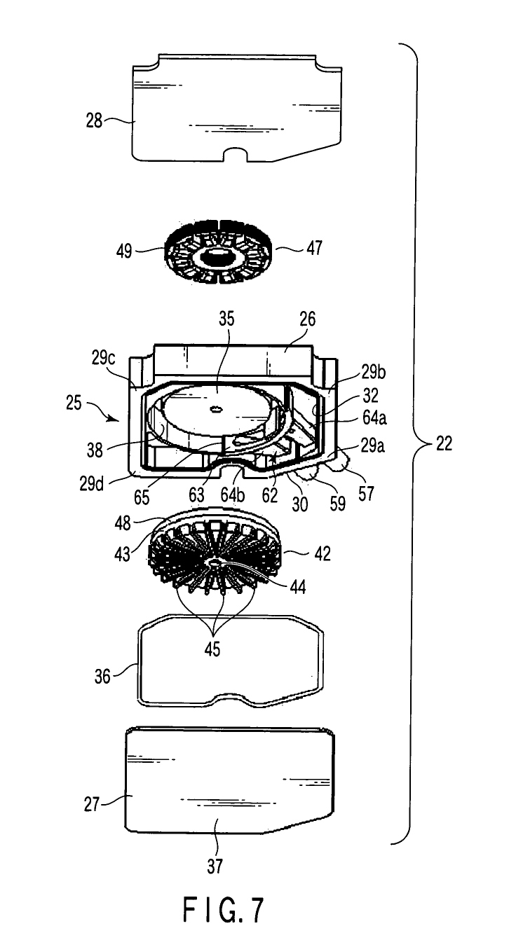

As shown in FIGS. 7 to 11, the casing body 26 has a cylindrical wall 38. The cylindrical wall 38 coaxially surrounds the cylindrical wall 34 of the second recess portion 33, and the lower end thereof adheres to the inner surface of the heat receiving cover 27. The cylindrical wall 38 divides the interior of the first recess portion 32 into a coolant flow path 39 and a reserve tank 40. The coolant flow path 39 also serves as a pump chamber. The coolant flow path 39 comprises a flat first region 39a and a groove-shaped second region 39b. The first region 39a is located between the heat receiving cover 27 and the end wall 35 of the second recess portion 33. The second region 39b is located between the cylindrical walls 34 and 38. The reserve tank 40, which stores the liquid coolant, surrounds the coolant flow path 39.

The coolant flow path 39 contains an impeller 42 made of synthetic resin 42. The impeller 42 has a disk-shaped main body 43 and a rotation shaft 44. The main body 43 is located in the first region 39a of the coolant flow path 39. The rotation shaft 44 is located at the center of the main body 43. The rotation shaft 44 extends between the end wall 35 of the second recess portion 33 and the heat receiving cover 27, and is rotatably supported by the end wall 35 and the heat receiving cover 27. The heat receiving cover 27 faces the lower surface of the main body 43. In this embodiment, the cylindrical wall 38 of the casing body 26 forms the peripheral surface of the coolant flow path 39, and the heat receiving cover 27 forms the end surface of the coolant flow path 39.

As shown in FIG. 5, there is a gap G1 between the lower surface of the main body 43 and the heat receiving cover 27. The gap G1 is filled with the liquid coolant and located just above the heat receiving surface 37. A plurality of blades 45 are formed on the lower surface of the main body 43. The blades 45 are extend radially from the center of rotation of the impeller 42 and exposed to the gap G1.

As shown in FIGS. 5 to 7, a flat motor 47 is incorporated in the casing body 26. The flat motor 47 has a rotor 48 and a stator 49. The rotor 48 is ring-shaped. The rotor 48 is coaxially fixed to the peripheral portion of the main body 43 of the impeller 42, and housed in the second region 39b of the coolant flow path 39. A ring-shaped magnet 50 is fitted in the rotor 48. The magnet 50 has a plurality of positive poles and a plurality of negative poles. The positive poles and the negative poles are arranged alternately in the circumferential direction of the magnet 50. The magnet 50 rotates integrally with the rotor 48 and the impeller 42.

The stator 49 is held in the second recess 33 of the casing body 26. The stator 49 is coaxially fitted in the magnet 50 in the rotor 48. The peripheral wall 34 of the second recess 33 is interposed between the stator 49 and the magnet 50. A control board 51, which controls the flat motor 47, is supported by the upper surface of the casing body 26. The control board 51 is electrically connected to the stator 49.

Power is supplied to the stator 49, for example, at the same time as the portable computer 1 is powered on. The power supply generates a rotary magnetic field in the circumferential direction of the stator 49. The magnetic field magnetically couples with the magnet 50 of the rotor 48. As a result, torque along the circumferential direction of the rotor 48 is generated between the stator 49 and the magnet 50, and accordingly the impeller 42 rotates.

The back plate 28 is fixed to the upper surface of the casing body 26. The back plate 28 covers the stator 49 and the control board 51.

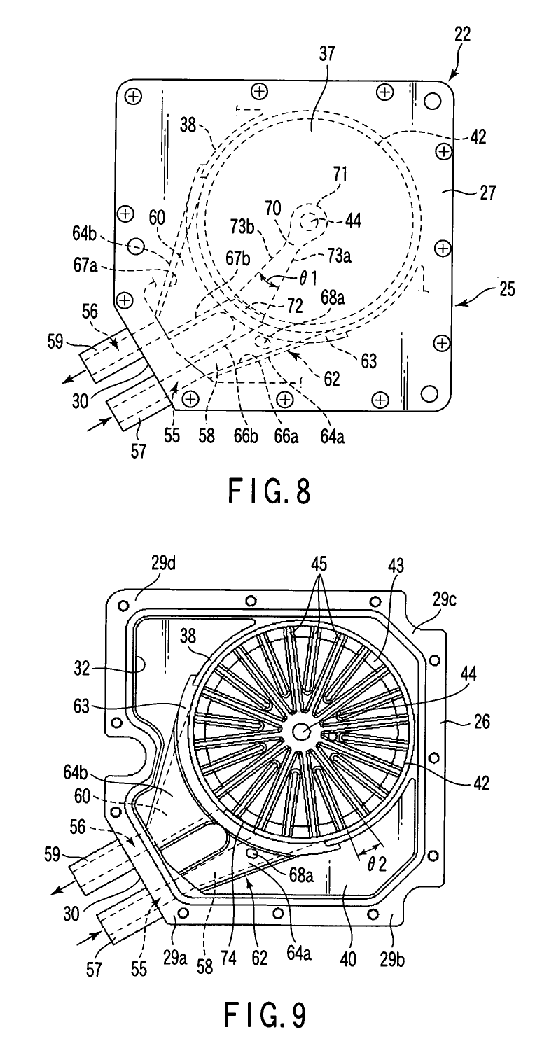

As shown in FIGS. 8 to 11, the casing body 26 has an inlet path 55, through which the liquid coolant is guided to the coolant flow path 39, and an outlet path 56, through which the liquid coolant is discharged from the coolant flow path 39. The inlet path 55 comprises an inlet 57 and a first connection path 58. The inlet 57 is formed integral with the casing body 26. The first connection path 58 connects the inlet 57 and the coolant flow path 39. The outlet path 56 comprises an outlet 59 and a second connection path 60. The outlet 59 is formed integral with the casing body 26. The second connection path 60 connects the outlet 59 and the coolant flow path 39.

The inlet 57 and the outlet 59 extend parallel to each other outward from the oblique side portion 30 of the casing body 26. The inlet 57 has an opening end 57a, which is opened to the outside of the casing body 26. The cross section of the inlet 57, including the opening end 57a, is circular. Likewise, the outlet 59 has an opening end 59a, which is opened to the outside of the casing body 26. The cross section of the outlet 59, including the opening end 59a, is circular. The diameter of each of the inlet 57 and the outlet 59 is the same throughout its length.

The first connection path 58 and the second connection path 60 are formed in a connection block 62. The connection block 62 is a part, which is independent of the casing body 26 and made of, for example, heat resistant synthetic resin material. As shown in FIGS. 9 to 11, the connection block 62 has an arc-shaped wall 63 and a pair of cylindrical portions 64a and 64b projecting from the wall 63. The wall 63 is fitted in a cut 65 formed in the cylindrical wall 38. In other words, the wall 63 closes the cut 65 and continues to the cylindrical wall 38. Consequently, the wall 63 functions as a part of the cylindrical wall 38.

The cylindrical portions 64a and 64b are arranged parallel to each other with a distance therebetween, and interposed between the wall 63 and the oblique side portion 30 of the casing body 26. The proximal ends of the cylindrical portions 64a and 64b abut on the inner surface of the oblique side portion 30. Further, the wall 63 of the connection block 62 is sandwiched between the bottom of the first recess portion 32 and the heat receiving cover 27. As a result, the connection block 62 is fixed to the casing body 26 across the interior of the reserve tank 40.

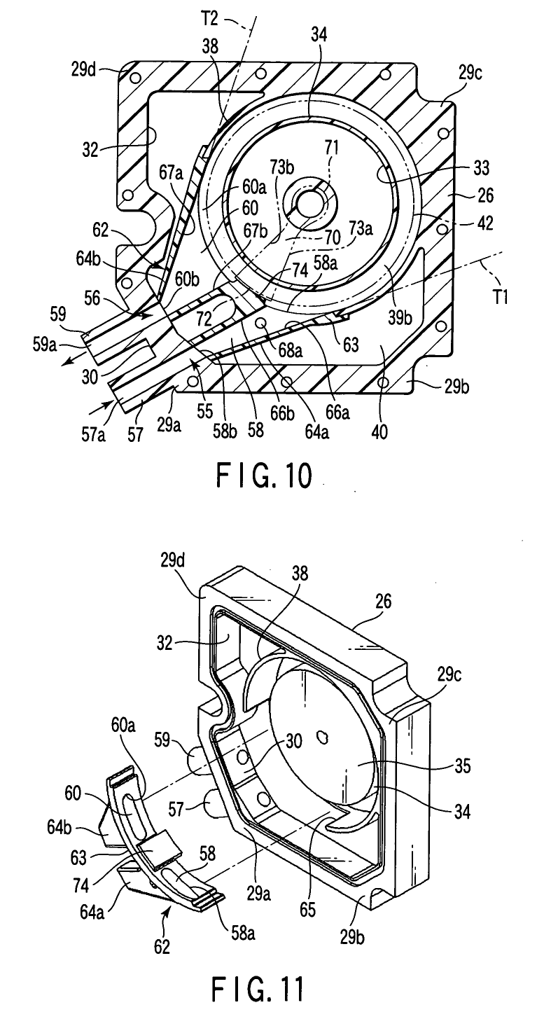

As shown in FIGS. 10 to 13, the cylindrical portion 64a constitutes the first connection path 58. The first connection path 58 has a first opening end 58a and a second opening end 58b. The first opening end 58a is opened in the wall 63 of the connection block 62 and exposed to the coolant flow path 39. The second opening end 58b is located at the upstream end of the first connection path 58, i.e., the opposite end from the first opening end 58, and connected to the inlet 57.

The other cylindrical portion 64b constitutes the second connection path 60. The second connection path 60 has a first opening end 60a and a second opening end 60b. The first opening end 60a is opened in the wall 63 of the connection block 62 and exposed to the coolant flow path 39. The second opening end 60b is located at the upstream end of the second connection path 60, i.e., the opposite end from the first opening end 60a, and connected to the outlet 59.

As shown in FIG. 10, the first opening end 58a of the first connection path 58 and the first opening end 60a of the second connection path 60 face the periphery of the impeller 42. They are adjacent to each other along the direction of rotation of the impeller 42. Each of the first opening end 58a and the first opening end 60a has an elliptic shape, whose longer axis extends along the direction of rotation of the impeller 42.

Each of the second opening end 58b of the first connection path 58 and the second opening end 60b of the second connection path 60 has a circular shape. The diameters of the second opening ends 58b and 60b are the same as the diameters of the inlet 57 and the outlet 59.

FIG. 10 is a sectional view showing the state that the casing body 26 is cut in the direction perpendicular to the rotation shaft 44 of the impeller 42. Referring to FIG. 10, the first connection path 58 has a pair of inner edges 66a and 66b, which face each other. The inner edges 66a and 66b are oblique to each other so that the distance therebetween increases from the second opening end 58b toward the first opening end 58a.

In other words, the first connection path 58 is wider as the distance from the inlet 57 in a direction toward the coolant flow path 39 is longer. Consequently, the area of the opening at the first opening end 58a is larger than the area of the opening at the second opening end 58b. Further, the inner edge 66a of the first connection path 58 is oblique to the inner edge 66b, so that it extends along a tangent line T1 of the cylindrical wall 38, which defines the coolant flow path 39. Thus, the shape of the cross section of the first connection path 58, across the direction of flow of the liquid coolant, continuously changes from the first opening end 58a to the second opening end 58b.

Referring to FIG. 10, the second connection path 60 has a pair of inner edges 67a and 67b, which face each other. The inner edges 67a and 67b are oblique to each other so that the distance therebetween increases from the second opening end 60b toward the first opening end 60a.

In other words, the second connection path 60 is wider as the distance from the outlet 59 in a direction toward the coolant flow path 39 is longer. Consequently, the area of the opening at the first opening end 60a is larger than the area of the opening at the second opening end 60b. Further, the inner edge 67a of the second connation path 60 is oblique to the inner edge 67b, so that it extends along a tangent line T2 of the cylindrical wall 38, which defines the coolant flow path 39. Thus, the shape of the cross section of the second connection path 60, across the direction of flow of the liquid coolant, continuously changes from the first opening end 60a to the second opening end 60b.

As shown in FIG. 10, the inner edge 66a of the first connection path 58 and the inner edge 67a of the second connection path 60 are oblique to the inner edges 66b and 67b in the opposite directions. In this embodiment, the oblique angle of the inner edge 67a with respect to the outlet 59 is greater than the oblique angle of the inner edge 66a with respect to the inlet 57.

As shown in FIG. 13, the cylindrical portion 64a of the connection block 62 has a pair of gas-liquid separating through holes 68a and 68b. The through holes 68a and 68b are respectively opened in the upper and lower surfaces of the cylindrical portion 64a, and connect the first connection path 58 and the reserve tank 40. The through holes 68a and 68b are always located under the surface of the liquid coolant stored in the reserve tank 40, regardless of the posture of the heat exchange-type pump 22.

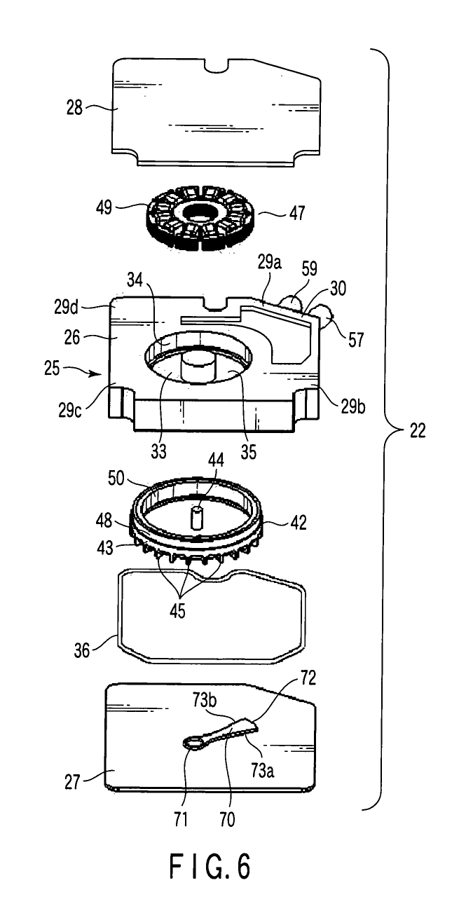

As shown best in FIGS. 5 and 6, the heat receiving cover 27 has a first projection 70. The first projection 70 is formed integral with the heat receiving cover 27 by casting or forging. The first projection 70 projects from the heat receiving cover 27 to the blades 45 of the impeller 42 and is located in the gap G1 between the impeller 42 and the heat receiving cover 27. The first projection 70 extends from the center of rotation of the impeller 42 in a radial direction of the impeller 42.

The first projection 70 has a ring-shaped first end portion 71, which receives the rotation shaft 44 of the impeller 42, a second end portion 72 opposite to the first end portion 71, and a pair of edge portions 73a and 73b connecting the first end portion 71 and the second end portion 72. As shown in FIG. 8, the edge portions 73a and 73b extend radially from the center of rotation of the impeller 42. The angle θ1 defined by the edge portions 73a and 73b is substantially the same as the angle θ defined by the adjacent blades 45 of the impeller 42.

As shown in FIG. 10, the second end portion 72 of the first projection 70 is located between the first opening end 58a of the first connection path 58 and the first opening end 60a of the second connection path 60. The edge portion 73a of the first projection 70 is connected to the inner edge 66b of the first connection path 58. Likewise, the other edge portion 73b of the first projection 70 is connected to the inner edge 67b of the second connection path 60.

As shown in FIGS. 10 and 11, the wall 63 of the connection block 62 has a second projection 74. The second projection 74 projects from that portion of the wall 63, which is located between the first opening end 58a of the first connection path 58 and the first opening end 60a of the second connection path 60, into the second region 39b of the coolant flow path 39. The second projection 74 faces the periphery of the impeller 42.

The second end portion 72 of the first projection 70 is connected to the lower end of the second projection 74. Thus, the first and second projections 70 and 74 are exposed to the coolant flow path 39 and define the flow route of the liquid coolant in the coolant flow path 39.

The heat exchange-type pump 22 is placed on the printed circuit board 16 with the heat receiving cover 27 facing the CPU 17. The pump casing 25 of the heat exchange-type pump 22 is fixed to the bottom wall 4b of the first housing 4 together with the printed circuit board 16. The bottom wall 4b has three boss portions 76 in the peripheral portion of the pump casing 25. The boss portions 76 project upward from the bottom wall 4b. The printed circuit board 16 is placed on the top end faces of the boss portions 76.

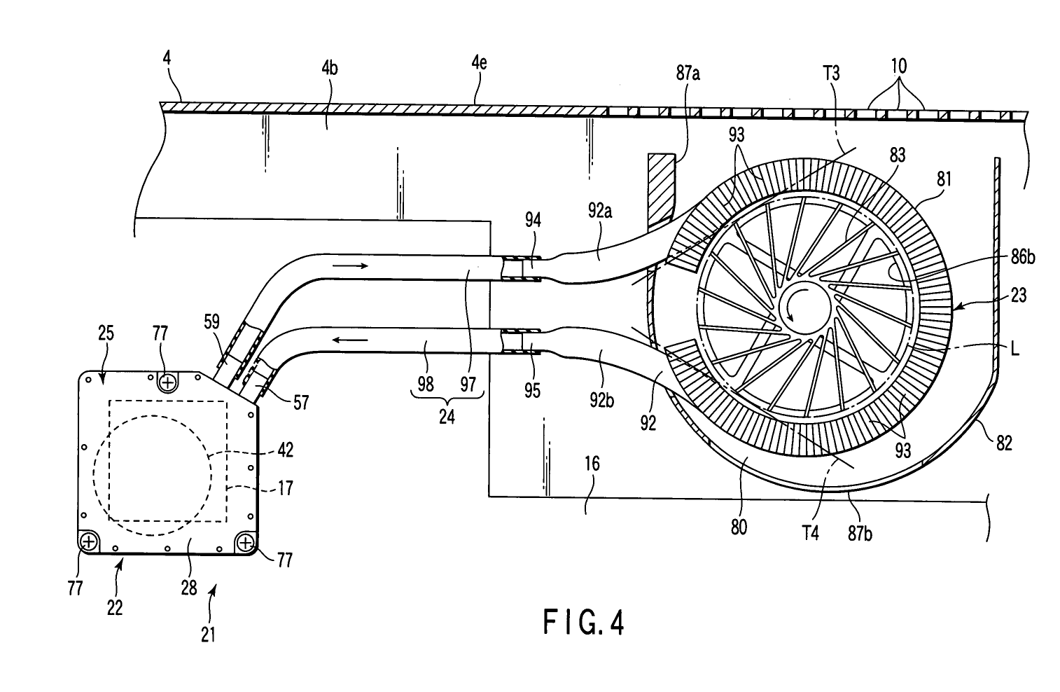

As shown in FIG. 4, screws 77 are inserted through the three portions of the peripheral portion of the pump casing 25 from above. The screws 77 are passed through the heat receiving cover 27 and the printed circuit board 16 and screwed into the boss portions 76. With this screwing, the pump casing 25 and the printed circuit board 16 are fixed to the bottom wall 4b and the heat receiving surface 37 of the heat receiving cover 27 is thermally connected to the IC chip 19 of the CPU 17.

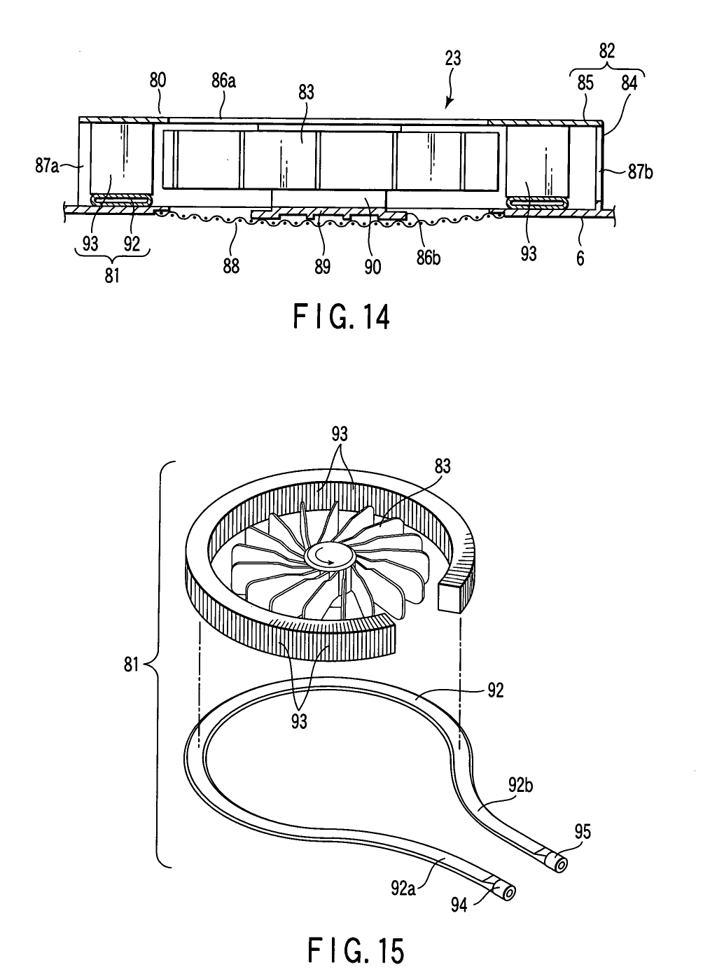

The radiator 23 of the cooling unit 21 is contained in the projected portion 6 of the first housing 4. As shown in FIGS. 4 and 14, the radiator 23 comprises a fan 80 and a heat radiating block 81. The fan 80 has a flat case 82 and a centrifugal impeller 83. The impeller 83 is housed in the case 82. The case 82 comprises a case body 84 and a top plate 85. The case body 84 is formed integral with the bottom of the projected portion 6 and perpendicular to the bottom. The top plate 85 is fixed to the upper end of the case body 84 and faces the bottom of the projected portion 6.

The case 84 has a pair of intake holes 86a and 86b and a pair of exhaust holes 87a and 87b. The intake hole 86a is opened in a central portion of the top plate 85. The other intake hole 86b is opened in the bottom of the projected portion 6. The intake hole 86b is covered by a mesh-like guard 88, which prevents foreign materials from being entering the case. Further, a disk-shaped motor supporting portion 89 is provided inside of the intake hole 86b.

The exhaust holes 87a and 87b are formed in the case body 84. The exhaust hole 87a has an elongated opening, which extends in the width direction of the first housing 4. It opens toward the first exhaust ports 12 in the rear wall 4e. The other exhaust hole 87b is located in the opposite side from the exhaust hole 87a, and opens toward the second exhaust port 12 in the dividing wall 11.

The impeller 83 is supported by the motor supporting portion 89 via a flat motor 90. The impeller 83 is located between the intake holes 86a and 86b. The flat motor 90 rotates the impeller 83 counterclockwise as indicated by the arrow in FIG. 4. With this rotation, negative pressure acts on the intake holes 86a and 86b and the air outside the case 82 is sucked in the central portion of the rotation of the impeller 83 through the intake holes 86a and 86b. The sucked air is blown radially by the centrifugal force from the periphery of the impeller 83.

The heat radiating block 81 of the radiator 23 is located between the case 82 and the impeller 83. As shown in FIGS. 4 and 15, the heat radiating block 81 has a coolant path 92, through which the liquid coolant flows, and a plurality of heat radiating fins 93. The coolant path 92 is composed of, for example, a flat copper pipe, and forms a ring shape which coaxially surrounds the impeller 83. The coolant path 92 is laid on the bottom of the projected portion 6 and thermally connected to the first housing 4.

The coolant path 92 has an upstream end portion 92a and a downstream end portion 92b. The ends of upstream end portion 92a and the downstream end portion 92b are arranged side by side, extend outward in the radial direction of the impeller 83 and pass through the case body 84. The upstream end portion 92a and the downstream end portion 92b of the coolant path 92 curve in contact with tangent lines T3 and T4 of a locus L of rotation having a large curvature drawn by the periphery of the impeller 83, and extend outward in the radial direction of the impeller 83. Further, the distance between the upstream end portion 92a and the downstream end portion 92b is continuously decreases toward the ends thereof.

The cross section of the upstream end portion 92a of the coolant path 92 gradually changes to a circle toward the end. The end of the upstream end portion 92a constitutes a coolant inlet 94, through which the coolant flows in. Likewise, the cross section of the downstream end portion 92b of the coolant path 92 gradually changes to a circle toward the end. The end of the downstream end portion 92b constitutes a coolant outlet 95, through which the coolant flows out.

The heat radiating fin 93 is a rectangular plate, which is made of metal having a high thermal conductivity, for example, an aluminum alloy. The heat radiating fins 93 are arranged radially at intervals along the periphery of the impeller 83.

The lower ends of the heat radiating fins 93 are fixed to the upper surface of the coolant path 92 by soldering or the like. The upper ends of the heat radiating fins 93 abut on the inner surface of the top plate 85 and are thermally connected to the top plate 85.

As shown in FIG. 4, the circulation path 24 of the cooling unit 21 has a first pipe 97 and a second pipe 98. The first pipe 97 connects the outlet 59 of the heat exchange-type pump 22 and the coolant inlet 94 of the coolant path 92. The second pipe 98 connects the inlet 57 of the heat exchange-type pump 22 and the coolant outlet 95 of the coolant path 92. As a result, the liquid coolant circulates between the heat exchange-type pump 22 and the radiator 23 through the first and second pipes 97 and 98.

An operation of the cooling unit 21 will now be described.

During use of the portable computer 1, the IC chip 19 of the CPU 17 generates heat. The heat generated by the IC chip 19 is transmitted to the pump casing 25 via the heat receiving surface 37. The coolant flow path 39 and the reserve tank 40 of the pump casing 25 are filled with the liquid coolant. The liquid coolant absorbs the heat generated by the CPU 17 and transmitted to the pump casing 25.

The first region 39a of the coolant flow path 39 faces the IC chip 19 of the CPU 17 with the heat receiving cover 27 interposed therebetween. Therefore, the liquid coolant in the first region 39a efficiently receives the heat from the IC chip 19.

Power is supplied to the stator 49 of the flat motor 47 at the same time as the portable computer 1 is powered on. The power supply generates torque between the stator 49 and the magnet 50 of the rotor 48, so that the rotor 48 rotates together with the impeller 42.

As the impeller 42 rotates, kinetic energy is applied to the liquid coolant flowing into the coolant flow path 39 through the inlet path 55. The kinetic energy gradually increases the pressure of the liquid coolant flowing in the coolant flow path 39. The pressurized liquid coolant is pushed out of the coolant flow path 39 to the outlet path 56, and supplied to the radiator 23 through the first pipe 97.

The liquid coolant supplied to the radiator 23 flows into the coolant path 92 through the coolant inlet 94, and flows in the coolant path 92 toward the coolant outlet 95. In the process of this flow, the heat generated by the IC chip 19 and absorbed by the liquid coolant is transmitted to the coolant path 92, and then transmitted to the heat radiating fins 93 through the coolant path 92.

According to this embodiment, the upstream end portion 92a and the downstream end portion 92b of the coolant path 92 curve in contact with tangent lines of the impeller 83, and extend outward in the radial direction of the impeller 83. Therefore, when the liquid coolant flows in the coolant path 92 and when the liquid coolant flows out of the coolant path 92, the flow resistance can be suppressed to be low.

The fan 80 of the radiator 23 starts operating, for example, when the temperature of the CPU 17 reaches a predetermined value. With the start of operation of the fan 80, the impeller 83 rotates and cooling air is blown radially from the periphery of the impeller 83. The cooing air passes between the adjacent heat radiating fins 93. As a result, the coolant path 92 and the heat radiating fins 93 are forcibly cooled, and the most part of the heat transmitted to these parts is discharged out together with the flow of the cooling air.

The cooling air that passed between the heat radiating fins 93 is discharged to the outside of the main unit 2 from the exhaust holes 87a and 87b of the case 82 through the first and second exhaust ports 10 and 12 of the first housing 4.

The liquid coolant, which has been cooled by the radiator 23, flows out through the coolant outlet 95 and returns to the inlet 57 of the heat exchange-type pump 22 through the second pipe 98. The liquid coolant is guided to the coolant flow path 39 from the inlet 57 through the first connection path 58.

The first connection path 58 has through holes 68a and 68b, which are open to the inside of the reserve tank 40. Therefore, part of the liquid coolant flowing in the first connection path 58 is discharged into the reserve tank 40 through the through holes 68a and 68b. As a result, if bubbles are contained in the liquid coolant flowing through the first connection path 58, they can be guided to the reserve tank 40 and removed from the liquid coolant.

The liquid coolant guided to the coolant flow path 39 is pressurized again by the rotation of the impeller 42, and sent out toward the radiator 23 through the outlet 59. Thus, the heat generated by the IC chip is successively transmitted to the radiator 23 by the circulation of the liquid coolant described above.

According to the first embodiment of the present invention, the liquid coolant returned to the inlet 57 of the heat exchange-type pump 22 is passed through the first connection path 58 and sucked in the coolant flow path 39 via the first opening end 58a. The liquid coolant sucked in the coolant flow path 39 is pressurized by the rotating impeller 42 and flows in the coolant flow path 39 along the direction of rotation of the impeller 42.

The area of the first opening end 58a of the first connection path 58 is larger than that of the second opening end 58b located upstream of the first opening end 58a. In addition, the inner edge 66a of the first connection path 58 is oblique to the inner edge 66b, so that it extends along the tangent line T1 of the cylindrical wall 38 surrounding the impeller 42. Due to the obliquity, the direction of opening of the first opening end 58a of the first connection path 58 is shifted from the center of rotation of the impeller 42 radially outward.

As a result, the direction of the flow of the liquid coolant when the liquid coolant is sucked in the coolant flow path 39 of the heat exchange-type pump 22 is substantially coincides with the direction of the rotation of the impeller 42. Accordingly, the liquid coolant smoothly flows into the coolant flow path 39 through the first opening end 58a of the first connection path 58. Therefore, the flow resistance of the liquid coolant is suppressed to be low.

The liquid coolant sucked in the coolant flow path 39 travels in the first and second regions 39a and 39b of the coolant flow path 39 along the direction of the rotation of the impeller 42. Then, the liquid coolant then reaches the connection portion between the first opening end 60a of the second connection path 60 and the coolant flow path 39.

The area of the first opening end 60a of the second connection path 60 is larger than that of the second opening end 60b located downstream of the first opening end 60a. In addition, the inner edge 67a of the second connection path 60 is oblique to the inner edge 67b, so that it extends along the tangent line T2 of the cylindrical wall 38 surrounding the impeller 42. Due to the obliquity, the first opening end 60a has such a shape that can easily receive the liquid coolant discharged by the impeller 42.

Owing to the above structure, the liquid coolant supplied to the connecting portion between the coolant flow path 39 and the second connection path 60 smoothly flows through the first opening end 60a of the second connection path 60. As a result, the pressurized liquid coolant is prevented from stagnating near the connecting portion between the coolant flow path 39 and the second connection path 60. Consequently, the high-temperature liquid coolant, which has absorbed the heat generated by the IC chip 19, can be efficiently discharged out of the coolant flow path 39 into the outlet path 56.

In addition, according to the above structure, the heat receiving cover 27 has the first projection 70 extending from the center of rotation of the impeller 42 to the portion between the first opening end 58a of the first connection path 58 and the first opening end 60a of the second connection path 60. Further, the wall 63 of the connection block 62 facing the periphery of the impeller 42 has the second projection 74 projecting toward the periphery of the impeller 42. The second projection 74 is connected to the first projection 70 inside the coolant flow path 39.

In other words, the first and second projections 70 and 74, which are interposed in the coolant flow path 39, define the upstream end and the downstream end of the coolant flow path 39. Thus, the inlet 57 is connected to the upstream end of the coolant flow path 39, while the outlet 59 is connected to the downstream end of the coolant flow path 39.

Owing to the above structure, the first and second projections 70 and 74 prevent the liquid coolant flowing in the coolant flow path 39 through the first opening end 58a of the first connection path 58 from flowing back toward the first opening end 60a of the second connection path 60 adjacent to the first opening end 58a. Thus, the liquid coolant guided to the coolant flow path 39 through the inlet 57 flows in the coolant flow path 39 along the direction of rotation of the impeller 42.

Further, when the liquid coolant reaches near the connecting portion between the coolant flow path 39 and the second connection path 60, the direction of the flow of the liquid coolant is controlled toward the first opening end 60a of the second connection path 60 by the first and second projections 70 and 74. Therefore, most part of the liquid coolant smoothly flows in the first opening end 60a.

Thus, while the heat exchange-type pump 22 efficiently absorbs the heat of the IC chip 19 by means of the liquid coolant, it can efficiently suck and discharge the liquid coolant. As a result, the efficiency of the circulation of the liquid coolant increases, so that the heat of the IC chip 19 can be quickly transmitted to the radiator 23. Consequently, the CPU 17 can be efficiently cooled and the operation environment of the CPU 17 can be maintained properly.

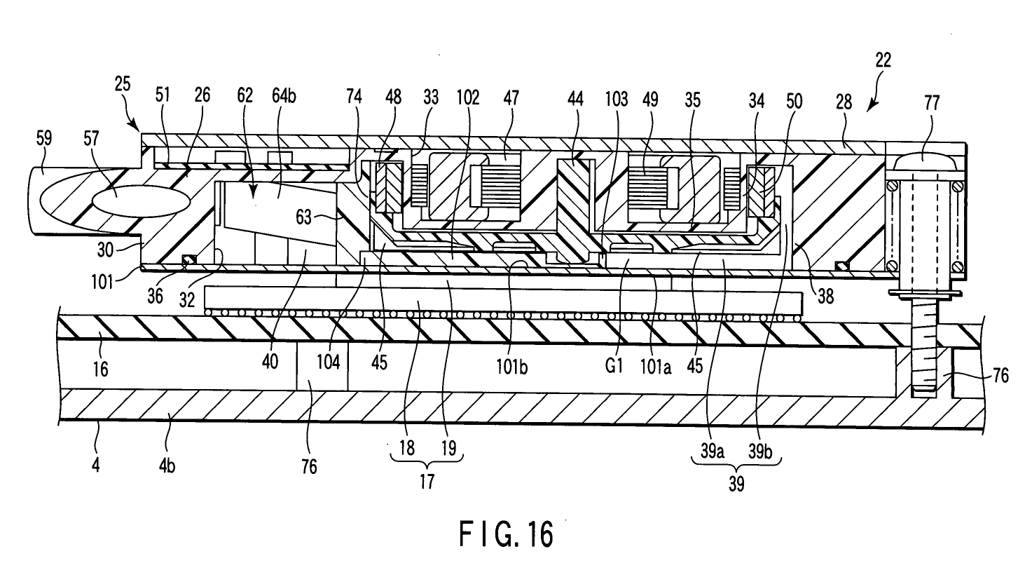

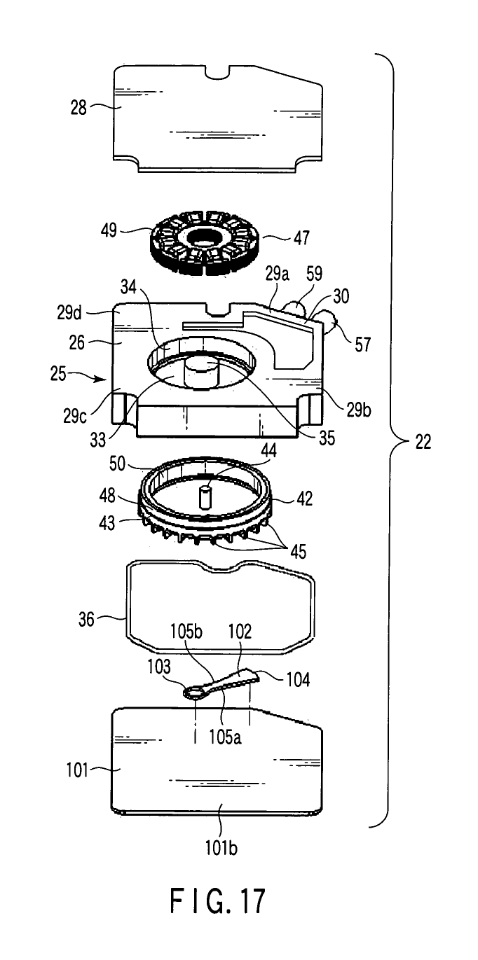

The present invention is not limited to the first embodiment described above. FIGS. 16 and 17 show a second embodiment of the present invention.

In the second embodiment, a heat receiving cover 101 of the pump casing 25 is different in structure from the heat receiving cover 27 of the first embodiment. The other portions of the heat exchange-type pump 22 are the same as those in the first embodiment in structure. Therefore, the portions of the second embodiment which are the same as those of the first embodiment are identified by the same reference numerals as those used for the first embodiment, and the description thereof is omitted.

The heat receiving cover 101 is made of, for example, a flat metal plate, which has been produced by sheet metal press working. The heat receiving cover 101 has a heat receiving surface 101a, which is thermally connected to the IC chip 19, and an inner surface 101b on the opposite side from the heat receiving surface 101a. The inner surface 101b is exposed to the coolant flow path 39 and faces the impeller 42.

A first projection 102 is provided on the inner surface 101b of the heat receiving cover 101. The first projection 102 is a part independent of the heat receiving cover 101, and made of, for example, a heat resistant synthetic resin material. The first projection 102 has a ring-shaped first end portion 103, which receives the rotation shaft 44 of the impeller 42, a second end portion 104 located immediately before the wall 63 of the connection block 62, and a pair of edge portions 105a and 105b connecting the first end portion 103 and the second end portion 104.

The first projection 102 is fixed, for example, to the inner surface 101b of the heat receiving cover 101 by adhesive. The first projection 102 extends from the center of rotation of the impeller 42 to a portion between the first opening end 58a of the first connection path 58 and the first opening end 60a of the second connection path 60.

According to the second embodiment described above, since the first projection 102 is made of a part independent of the heat receiving cover 101, an inexpensive pressed part can be used as the heat receiving cover 101. Therefore, the cost of the heat exchange-type pump 22 can be reduced.

In the second embodiment, the first projection is made of a synthetic resin, but it may be made of, for example, a metal.

In the first embodiment, the resin block, which constitutes parts of the inlet path and the outlet path, is independent of the casing body. However, the present invention is not limited to this structure. For example, the casing body and the resin block may be integrally formed as one unitary body. If the casing body and the resin block are integrally formed, the opening end of the outlet coincides with the second end of the outlet path, and the opening end of the inlet coincides with the second end of the inlet path.

Moreover, the heat generating component is not limited to the CPU, but may be any other circuit component, for example, a chip set.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A pump comprising:
a pump casing having a pump chamber, an inlet path through which a liquid is guided to the pump chamber and an outlet path through which the liquid is discharged from the pump chamber; and
an impeller, which is housed in the pump chamber, sucks the liquid through the inlet path into the pump chamber and pushes the liquid out of the pump chamber into the outlet path,
wherein the outlet path has a first opening end which is opened in the pump chamber, and a second opening end located downstream of the first opening end, the first opening end having an opening area larger than that of the second opening end.

2. The pump according to claim 1, wherein the inlet path has a first opening end which is opened in the pump chamber, and a second opening end located upstream of the first opening end, the first opening end having an opening area larger than that of the second opening end.

3. The pump according to claim 2, wherein each of the first opening end of the outlet path and the first opening end of the inlet path has an elliptic shape, whose longer axis extends along a direction of rotation of the impeller, and each of the second opening end of the outlet path and the second opening end of the inlet path has a circular shape.

4. The pump according to claim 2, wherein the pump casing has a first projection, which extends from a center of rotation of the impeller to a portion between the first opening end of the outlet path and the first opening end of the inlet path, and the first projection projects in the pump chamber.

5. The pump according to claim 4, wherein the pump casing has a cylindrical wall surrounding the impeller, the cylindrical wall having a second projection projecting from the portion between the first opening end of the outlet path and the first opening end of the inlet path toward a periphery of the impeller.

6. The pump according to claim 5, wherein the second projection is connected to the first projection in the pump chamber.

7. The pump according to claim 4, wherein the first projection has a pair of edge portions extending in radial directions of the impeller, one of the edge portions being connected to an inner surface of the inlet path and the other of the edge portions being connected to an inner surface of the outlet path.

8. The pump according to claim 4, wherein the first projection is made of a part independent of the pump casing.

9. The pump according to claim 1, wherein the outlet path becomes wider as the distance from the second opening end in a direction toward the first opening end is longer.

10. A cooling unit comprising:
a heat receiving portion which receives heat generated by a heat generating component;
a heat radiating portion which radiates the heat generated by the heat generating component; and
a circulation path which circulates a liquid coolant between the heat receiving portion and the heat radiating portion,
wherein the heat receiving portion includes:
a casing having a coolant flow path in which the liquid coolant flows, an inlet path through which the liquid coolant is guided to the coolant flow path and an outlet path through which the liquid coolant is discharged from the coolant flow path; and
an impeller, which is provided in the coolant flow path, sucks the liquid coolant through the inlet path into the coolant flow path and pushes the liquid coolant out of the coolant flow path into the outlet path, and
wherein the outlet path has a first opening end which is opened in the coolant flow path, and a second opening end located downstream of the first opening end, the first opening end having an opening area larger than that of the second opening end.

11. The cooling unit according to claim 10, wherein the inlet path of the heat receiving portion has a first opening end which is opened in the coolant flow path, and a second opening end located upstream of the first opening end, the first opening end having an opening area larger than that of the second opening end.

12. The cooling unit according to claim 11, wherein each of the first opening end of the outlet path and the first opening end of the inlet path has an elliptic shape, whose longer axis extends along a direction of rotation of the impeller, and each of the second opening end of the outlet path and the second opening end of the inlet path has a circular shape.

13. The cooling unit according to claim 10, wherein the heat radiating portion includes an impeller which blows cooling air, a coolant path which surrounds the impeller and allows passage of the liquid coolant heated by heat exchange with the heat generating component, and a plurality of radiating fins which are thermally connected to the coolant path.

14. The cooling unit according to claim 13, wherein the coolant path of the heat radiating portion has an upstream end portion through which the liquid coolant flows in and a downstream end portion through which the liquid coolant flows out, the upstream end portion and the downstream end portion forming a shape in contact with tangent lines of a locus of rotation drawn by a periphery of the impeller.

15. The cooling unit according to claim 10, wherein the coolant flow path of the casing is thermally connected to the heat generating component.

16. An electronic apparatus comprising:
a housing including a heat generating component; and
a cooling unit which cools the heat generating component by means of a liquid coolant, the cooling unit including a heat receiving portion which receives heat generated by the heat generating component, a heat radiating portion which radiates the heat generated by the heat generating component, and a circulation path which circulates the liquid coolant between the heat receiving portion and the heat radiating portion and transmits the heat generated by the heat generating component to the heat radiating portion via the liquid coolant,
wherein the heat receiving portion includes:
a casing having a coolant flow path in which the liquid coolant flows, an inlet path through which the liquid coolant is guided to the coolant flow path and an outlet path through which the liquid coolant is discharged from the coolant flow path; and
an impeller, which is provided in the coolant flow path, sucks the liquid coolant through the inlet path into the coolant flow path and pushes the liquid coolant out of the coolant flow path into the outlet path, and
wherein the outlet path has a first opening end which is opened in the coolant flow path, and a second opening end located downstream of the first opening end, the first opening end having an opening area larger than that of the second opening end.

17. The electronic apparatus according to claim 16, wherein the coolant flow path of the heat receiving portion is thermally connected to the heat generating component.
